(19) United States
(12) Patent Application Publication
(10) Pub. No.: US 2010/0117661 A1
(43) Pub. Date: May 13, 2010

(54) GRID TOUCH POSITION DETERMINATION

(76) Inventors: Frederick Johannes Bruwer, Paarl (ZA); Nico Johann Swanepoel, Paarl (ZA); Pieter Jacobus Pretorius, Paarl (ZA); Riaan Fourie, Paarl (ZA)

Correspondence Address: JONES, TULLAR & COOPER, P.C., P.O. BOX 2266 EADS STATION, ARLINGTON, VA, 22202, US

(21) Appl. No.: 12/531,275

(22) PCT Filed: Aug. 15, 2008
(86) PCT No.: PCT/ZA08/00072

§ 371 Date: Sep. 14, 2009

(30) Foreign Application Priority Data
Aug. 15, 2007 (ZA) 2007/06882
Oct. 4, 2007 (ZA) 2007/08988
Nov. 23, 2007 (ZA) 2007/10289
Apr. 9, 2008 (ZA) 2008/03137

(51) Int. Cl. G01R 27/26

(52) U.S. Cl. 324/662

(57) ABSTRACT

A capacitive sensing circuit which has a uniformly resistive sense plate, a charge transfer measurement circuit connected to one side of the sense plate and a dummy load which is only connected to another side of the sense plate during some measurement cycles.

### BACKGROUND OF THE INVENTION

This invention relates to the determination of a touch position on a grid.

Technologies for determining a touch position on a grid are well known in the art. However, it is necessary to use several sense channels to handle the different rows and columns. The same is true for sliders. For example, to implement a slider with 16 pads may require 5 or 6 sense channels in a more digital approach

In the art the use of capacitive or resistive touch screen structures is also well known. An important cost of these, when used to implement over screens (LCD, CRT etc), is the transparent conductive sheets (e.g. glass with ITO coating) that are used in several layers with insulating structures to keep the conductive elements apart until pressure is exerted at a point.

It is also important to optimise the relationship of the discharging rate from the touch capacitor (Ct) to the sense channels and the ratio of resistance formed in the sense plate around the point of contact in order to improve the accuracy and sensitivity of the system.

The invention aims to provide alternative touch position measurement techniques that are practical and cost-effective to implement.

### SUMMARY OF THE INVENTION

According to the invention a sensing circuit is configured so that only two inputs and only a single sensing channel together with the related resources to manage such capacitive sensing channel are required per one dimensional slider.

The invention also relates to an effective implementation of:
an auto calibration mechanism with limited cost implications,
a parasitic capacitance cancellation mechanism,
improved dependency of measurement on the ratio of resistances formed in a user interface structure,
cost effective driven shield implementation for two-dimensional sense plates.

“Sensing channel” as used herein includes an arrangement wherein an input/output pin is connected to a sense plate, and the pin is sequentially switched between a voltage to charge the sense plate and a reference capacitor into which the charged sense plate is discharged.

“A charge transfer cycle” or “a charge transfer measurement cycle” means a process of starting from a defined state (typically 0V) and repeating the process of charging the sense plate and discharging it into the reference capacitor (generally denoted Cs), as described in connection with the sensing channel, until the reference capacitor reaches a specific voltage (trip) level.

In the sensing circuit of the invention a capacitive sensor circuit provides an output that relates to a position of an object that is capacitively coupled with a resistive sense plate body that is connected between a capacitive sensing channel on a first side and a non-capacitive sensing circuit on a second side. (one dimension example)

The sensing circuit may make a connection to a dummy load on the second side during some charge transfer measurements cycles, and may create a floating, or open, circuit during other charge transfer measurements cycles.

The method relates to the capacitive sensing determination of a position on a conductive structure (e.g. a one dimensional slider) using the ratio of discharge of the touch capacitor (Ct—which is for example a user's finger) through the resistances formed on the slider.

In a first approach (shown in FIG. 4a) both sides of the slider are connected to a capacitive sensing channel and a normal charge transfer cycle is performed with both channels operation synchronously. It is clear that the ratio of resistances will determine the how much charge is transferred to each channel from the single touch point.

The following negatives of this implementation are described before techniques are given for improved performance.

(a) As one side is charged faster (smaller R in slider leg—side X₂ in FIG. 4a) the voltage on that sense channel reference capacitor rises faster. Since the touch capacitor Ct discharges to both sides, the voltage difference between Ct (when charged) and the reference capacitors in the two sides is no longer the same in subsequent charge/discharge cycles, and as such the discharge ratio does not purely reflect the ratio of resistances but also depends on the voltage difference of the two reference capacitors in the two sense channels. This influences the effect of the difference in the resistances formed in the slider on the measurements (see also FIG. 11).

In a novel solution, which works especially well with the single sense channel implementation to determining a position on a one dimensional slider, it is proposed to measure the number of charge transfer cycles only on one side of the slider. The other side of the slider is connected to a dummy load that is kept at the same voltage as the reference capacitor (Cs) of the sense channel side that is measured. The performance of the buffer, op amp etc that are used to keep the voltage on the dummy load equal to the voltage on the active sense channel Cs will affect the accuracy but in the ideal case the ratio of the resistances in the user interface between the point of touch and the two sides of the slider is now the only factor in the ratio of discharge from Ct to the reference capacitor (Cs) and the dummy load. This provides a measurement that accurately relates to the position of touch on the slider (FIG. 6b).

(b) in a related problem the Ct discharges faster to the level of the channel connected to it through the smaller resistance. This can first of all cause the Ct to discharge for a longer period to the sense channel with greater resistance during each discharge cycle, and can also cause the reference capacitor from the faster charging sense channel to discharge through the slider to the slower charging sense channel (cross bleeding).

Both issues cause the desired effect, i.e. discharging to be singularly related to the ratio of the resistances formed around the point of touch on the slider, to be diminished.

The use of diodes in the two discharging circuits can prevent cross bleeding. This will not however prevent the discharging of Ct to the slower side for a longer period of time and thus affecting the ratio of discharge. In order to keep the discharge time for both channels the same, it is suggested either to monitor the difference in voltage between the reference capacitors in both channels and Ct, or to monitor the flow of charge in both channels. If either measurement drops to a predetermined level (of course before cross bleeding occurs) the switches controlling the discharge of Ct to the reference capacitors on both channels are opened to halt all discharging.

The capacitive sensor may also perform a calibration procedure involving on-chip charge-increasing structures to emulate a touch or proximity event at least at one sense plate but without requiring such a physical external event.

In one embodiment for measuring a position on a 2 dimensional surface, the capacitive sensor includes a sense plate which uses material with a uniformly resistive surface that is divided into sectors using insulating lines (see FIG. 16).

It is practical to implement various types of sliders, scroll wheels and touch sensitive screens using only a single capacitive sensing channel per one-dimensional slider. In this regard it is also possible to treat the scroll wheel of a computer mouse as a one-dimensional slider structure which can be implemented using uniformly resistive structures. However a non-uniformly resistive structure can be used and can translate linear movement into a non-linear parameter.

In one form of the invention there is provided a capacitive sensing circuit for determining the position of an object proximate to, or in physical contact with, a sense plate, in one dimension of the sense plate which includes:
a charge transfer measurement channel connected to a first side of the sense plate,
with a second side of the sense plate connected to a dummy load during some charge transfer measurement cycles and during other measurement cycles the second side is not connected to the dummy load, and
   wherein the sense plate includes a uniformly resistive element between the first and second sides of the sense plate.

In another form the invention provides a capacitive sensing circuit for determining a two dimensional position of an object proximate to, or in physical contact with, a sense plate, with reference to the sense plate, including at least a charge transfer measurement circuit connected to at least one side of the sense plate in each dimension, wherein the sense plate includes a uniformly resistive element and the circuit is implemented in accordance with at least one of the following configurations;
(a) a charge transfer measurement channel is connected to at least one side of the sense plate which, in each dimension, is connected with multiple contacts with a switch for each contact and wherein no more than one of said switches in a dimension is closed when a measurement is made in the other dimension;
(b) a dummy load is connected through at least one contact and switch to a side of the sense plate, that is not connected to a measuring channel, in each dimension and wherein the at least one switch connecting the dummy load to the sense plate is closed during some measurements cycles and open during other measurements cycles; and
(c) at least two charge transfer measurement channels are connected to the sense plate in each dimension, one to each side, each measurement channel being connected with multiple contacts to the sense plate and a switch for each contact, and wherein no more than one of said switches per side in a dimension is closed when a charge transfer measurement is made in the other dimension

### BRIEF DESCRIPTION OF THE DRAWINGS

The invention is further described by way of examples with reference to the accompanying drawings in which:

FIG. 1 shows a two dimensional plate with X and Y pads insulated from each other;

FIGS. 2a to 2d show the construction of a two dimensional plate from an array of sliders;

FIG. 3 shows a two dimensional plate with discrete pads;

FIG. 4a shows a slider (one dimensional position determination) with a touch at position D;

FIGS. 4b to 4d show a two dimensional plate constructed with a uniformly resistive coating and its possible application;

FIGS. 5a to 5c show a schematic representation of the circuits required for two channel sensing of a slider and single sensing channel implementations using capacitor or resistor dummy loads;

FIG. 6 a depicts a slider;

FIG. 6b schematically shows circuitry required for a one channel sensing implementation using a buffer to regulate the dummy load voltage;

FIGS. 7a to 7c are graphs showing the results from slider measurements;

FIG. 8 shows the use of pad capacitance to cross connect;

FIG. 9 shows the use of pad capacitance to cross connect in a two dimensional plate;

FIGS. 10a and 10b are schematics for implementing auto calibration for one dimensional and two dimensional plates;

FIG. 11 is a diagram of a slider and switches for discharging into two sense channels;

FIG. 12 is a diagram of a slider with diodes in a discharging path and a charging path;

FIGS. 13a and 13b are auto calibration schematic diagrams;

FIG. 14 is a schematic diagram for a single channel slider measurement circuit with diodes in discharging paths;

FIG. 15 shows practical measurement results;

FIG. 16 shows a minimalist approach to measuring an array of sliders;

FIG. 17 shows a two dimensional plate using a single channel per dimension and a single contact per side;

FIGS. 18a and 18b show sense plate predicted measurement curves for a single contact per side;

FIG. 19a is a schematic of a structure to add a resistor to a measurement circuit;

FIG. 19b is a diagram showing resistive paths on a sense plate;

FIG. 20 shows a two dimensional sense plate with multiple contacts per side, wherein the contacts can be selected through switches connected to a sensing channel for each side;

FIG. 21 shows a uniformly resistive plate with a termination structure near each edge to improve the accuracy of measuring a point of touch;

FIG. 22 is a multiple contact per side sense plate connection diagram;

FIG. 23 shows a two dimensional sense plate with contacts at four corners;

FIG. 24 shows a multiple contact sense plate with contacts connected to sense channels through a star network of resistors;

FIG. 25 is a multiple contact per side diagram to illustrate how to select a specific contact per side for a discharging path from a touch capacitor Ct to the reference capacitor; and

FIG. 26 is a circuit diagram showing, in a two contact per side arrangement, on implementation of a minimal driven shield system.

### DESCRIPTION OF PREFERRED EMBODIMENTS

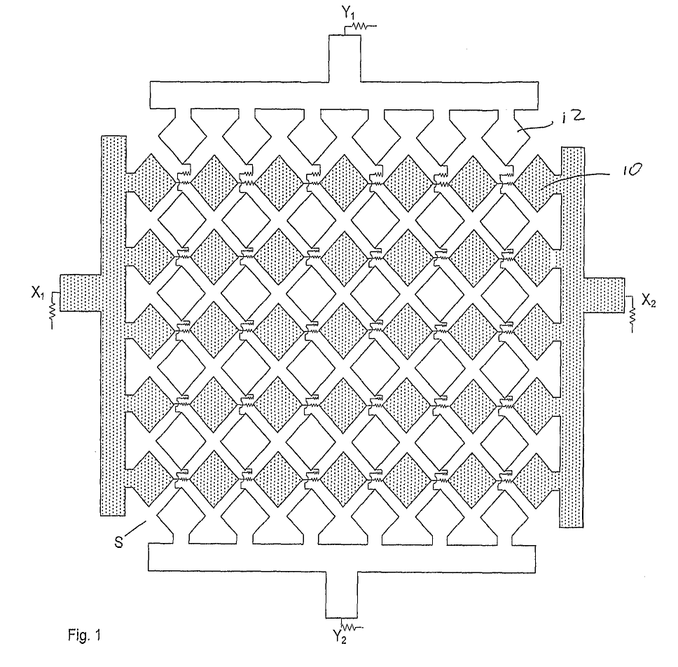

FIG. 1 shows a touch pad layout in which X₁ and X₂ are used in one dimension and Y₁ and Y₂ in a second dimension. The implementation in FIG. 1 also has the pads 10 for X₁ and X₂ insulated from the pads 12 for Y₁ and Y₂. This holds some advantage in some respects in terms of capacitance that is inherently part of the IC (integrated circuit) pad structure. To improve sensitivity the design of the sense plate and associated pads must minimize capacitance.

In some embodiments the pads may be small such that a touch with, for example, a finger will automatically affect several pads at once. This will have a smoothing effect in the case of discrete pads connected with resistive components.

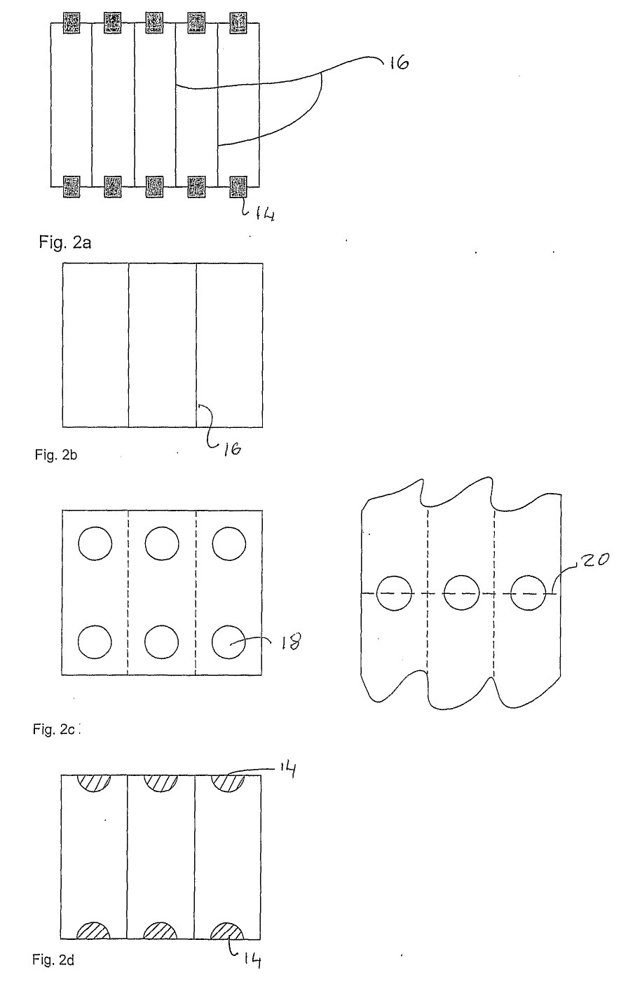

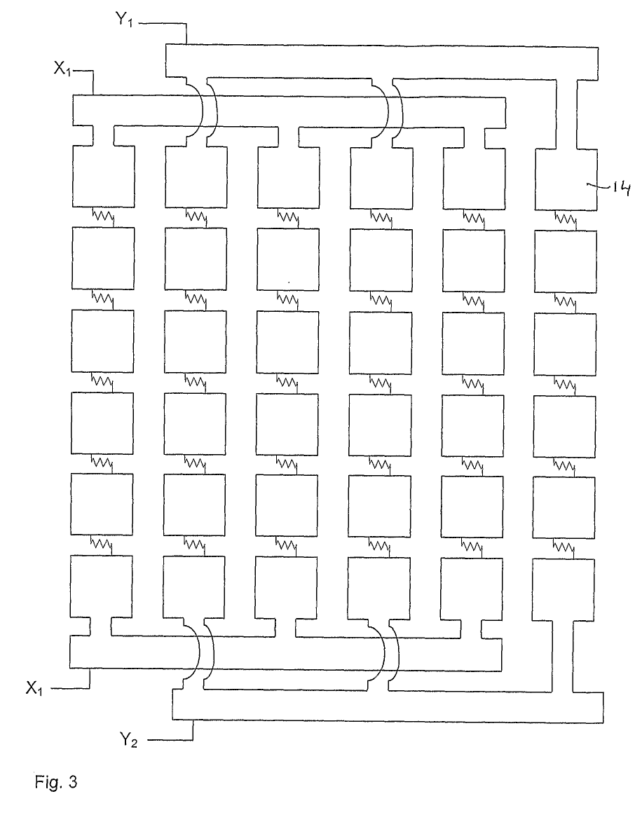

Another configuration is shown in FIG. 2a wherein the pads 14 in a uniformly resistive plate are connected in one dimension and separated in another dimension by insulating lines 16 essentially forming several one dimensional sliders. FIG. 3 shows a variation of the format in FIG. 2a. It is possible for an area S, between the pads, to be insulated from the pads and to be connected to a fixed reference (e.g. ground) in order to increase the separation between the pads.

FIGS. 2b,c,d indicate how to implement a touch sensitive pad structure using a non-conductive material (e.g. glass, perspex, plastic, ceramic etc) with a conductive surface on one side, creating several one-dimensional sliders (three in these Figures). By insulating areas of the plate with lines 16 created during manufacturing of the plate or made with suitable means such as for example lasers, sawing, cutting or etching, the sliders are defined. The insulating lines are preferably very thin and substantially invisible and must be protected against anything that would create electrical contact between the individual slider areas. In FIG. 2d the conducting side is covered by another layer of the same non-conductive material, thereby basically creating a sandwich structure with the conducting layer in the middle. Clearly access for a physical electrical connection is still required between both sides of every slider and the associated electronic circuit.

In FIG. 2c two practical methods are shown how to handle material such as for example glass where drilling holes 18 is feasible but cutting squares is not. In the second drawing in FIG. 2c a dotted line 20 which traverses the holes 18 indicates a cut line through the non-conductive material substrate.

FIG. 2d shows a combination of the plate in FIG. 2b and a plate formed in accordance with the second drawing in FIG. 2c to create very well protected slider areas but with easy access to the ends of the slider for electrical contact. Terminals and/or wires can then be attached to the conducting surface at the contact pads with, for example, conducting glue. In another embodiment the construction of the product may be such that when the plate as shown in FIG. 2d is attached it makes contact where required against a spring loaded terminal to ease assembly and manufacturing.

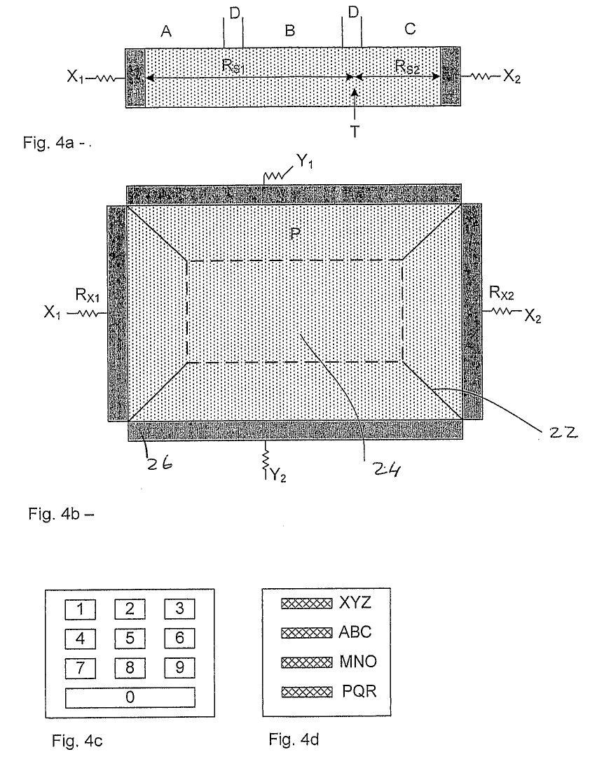

The sense pad may alternatively be a slider (FIG. 4a) or pad (FIG. 4b shows a uniform resistance to each pad), that is constructed using a material that is electrically conducting but with some resistance. In FIG. 4b a two dimensional structure is shown with some insulation in areas, provided by insulating dividing lines 22, to prevent the short distances (low resistance) from causing problems in the corners (essentially creating a short through the highly conductive sides of one dimension when measuring the other dimension). This creates an ideal centrally located touch pad section 24.

The resistance required is dependent on the size of the slider and the resolution of a charge transfer sensing unit as well as the resistance in a circuit from the physical plate to the measurement circuit. Solid areas 26 on the edges represent a low resistance contact region. FIGS. 4c and 4d illustrate possible user interface configurations.

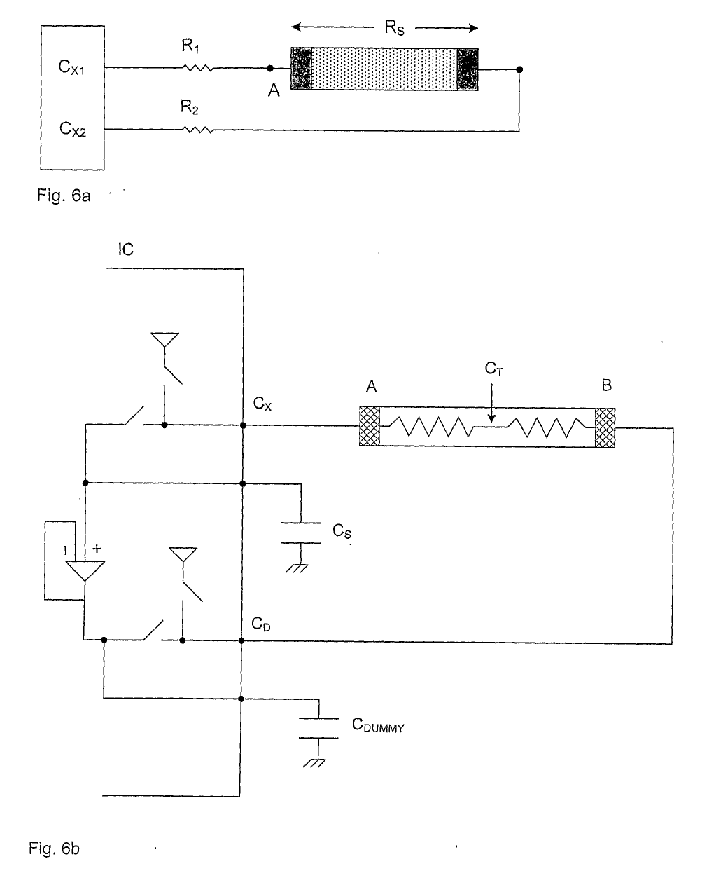

In FIG. 6a R_{S} denotes the resistance from one side of the slider divider structure to the other side (A to B). A touch at the A side causes an incremental change, referred to as a delta m, in transfer measurements through C_{X1}, when no slider is in place (or B is not connected to anything). The delta of m number of transfers is a measurement of the current, flowing from the charged touch capacitor (C_{T}) touching A, through R₁ and, hence, a measure of the size of Ct. The design may be such that a touch (with the same capacitor C_{T}) at B (without the slider in place) will also yield a delta of m transfers through C_{X2}. It is then clear to the skilled reader that the slider will divide the current in proportion to the resistances R₁, R_{S} and R₂ when a touch happens elsewhere on the slider and with both sides connected. R₁ and R₂ represent the full resistance in the circuit, including on-chip and switch resistances, and exclude a possible capacitance from the slider itself for simplification and explanational purposes. The above is known in the art (see Philipp U.S. Pat. No. 7,148,704 B2, Dec. 12, 2006).

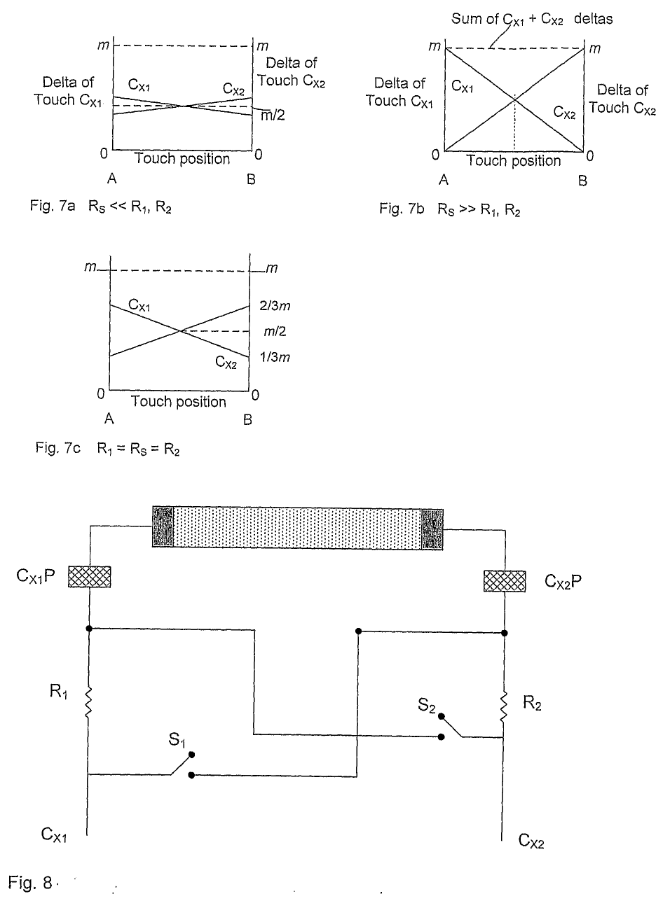

If R_{S} is small compared to R₁ and R₂ then the difference in the transfer delta when touching at A or touching at B (or in between) will be small—see FIG. 7a. If R_{S} is very big compared to R₁ and R₂, then touching at A will yield a very small change in measurement at C_{X2} and vice versa (See FIG. 7b). Touching in the middle of the slider will yield a similar result at C_{X1}, and C_{X2}.

If R₁=R₂=R_{S} (FIG. 7c) then the ratio of currents flowing through R₁ and R₂ with a touch at A will be:

$$\frac{{I}_{1}}{{I}_{2}} = \frac{{R}_{S} + {R}_{2}}{{R}_{1}}$$

i.e. I₁=2I₂;
and with a touch at the B side will be:

$$\frac{{I}_{1}}{{I}_{2}} = \frac{{R}_{2}}{{R}_{1} + {R}_{S}}$$

i.e. I₁=0.5I₂.

From the above it should be clear how to manipulate the R values to emphasize the desired parameter in transfer measurements. However, without a substantial difference in transfer measurement during a touch compared with the transfer when no touch occurs, the resolution (and the number of pads that can be handled/identified) will always be low. In general it is preferable that R_{S} should be large compared with R₁ and R₂.

For example, it may be desirable to have a 500 Ohm or 10 kOhm resistance across the pad in each dimension. However, as indicated, this is a function of the charge transfer circuit parameters and frequency. If a touch occurs and the touch capacitor C_{T} is charged, the RC values must be such that the sense plate and the touch capacitor are fully charged and fully discharged to the required levels within the charge and discharge periods. If not, the unit will lose accuracy, resolution and/or stability.

Clearly the pad/slider can be constructed from various materials, for example (but not limited to) glass, Perspex, ceramic or nylon with a conductive coating/paint or impregnated material that gives a consistent R across the structure (e.g. ITO glass).

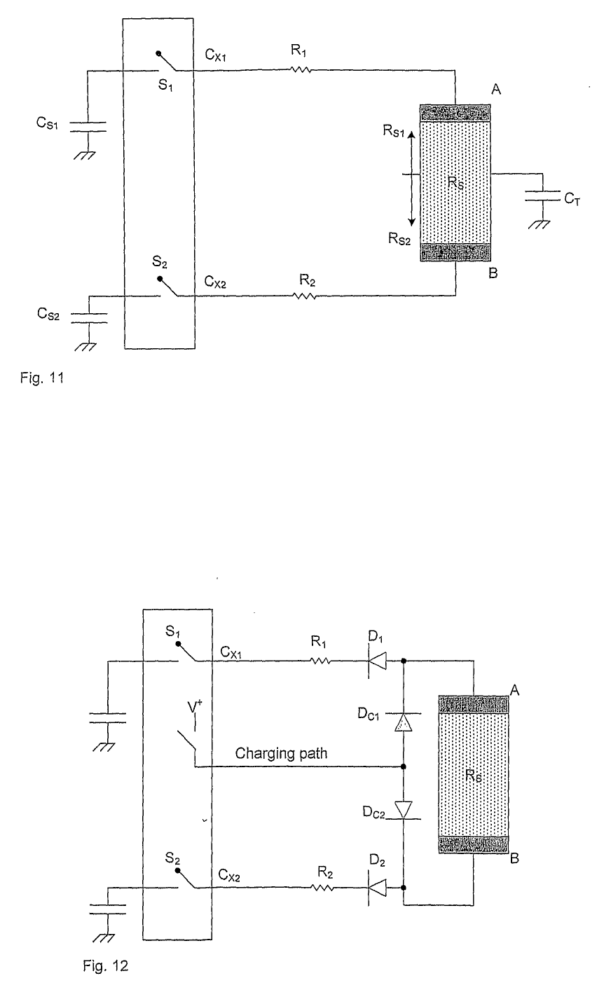

Referring again to FIG. 6a and to FIGS. 11, 14 and 16, a further improvement can be achieved in terms of reducing not only the number of sense channels but also the number of pins required to implement a multiple slider system to form a two dimensional pad.

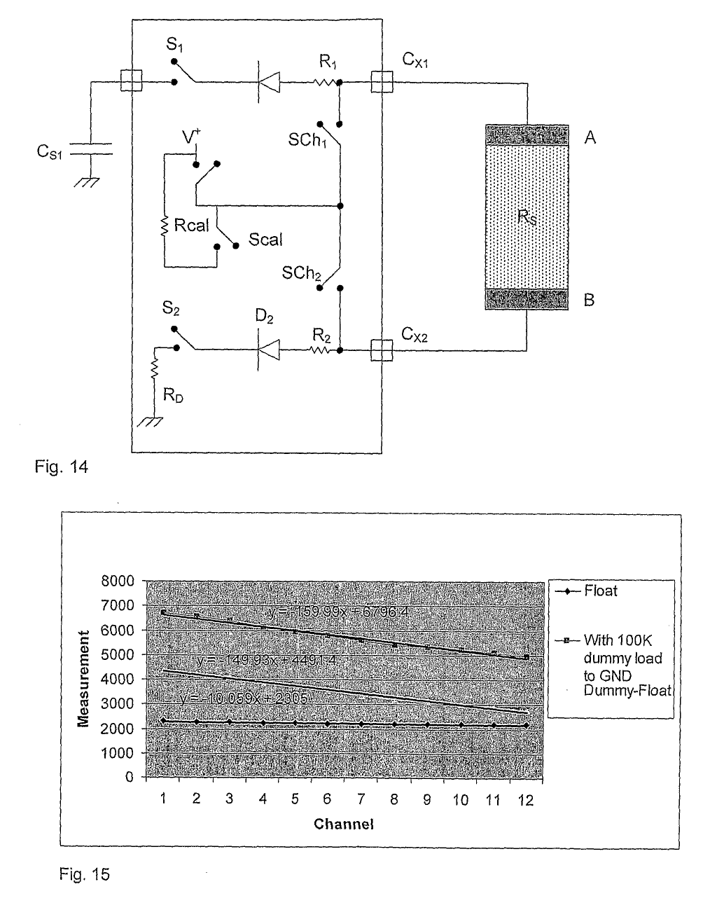

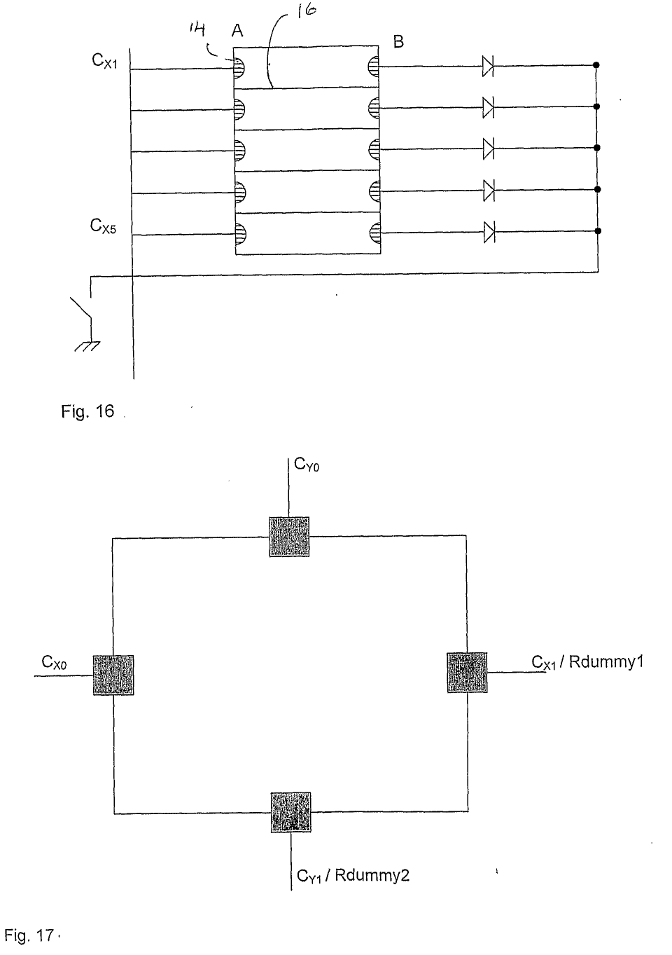

Firstly, all connections to the B side of the sliders pass through switches and are then connected together in a single circuit line that is tied to a dummy load. (see FIGS. 14 and 16) This means that only one slider section can be handled at a time with a single Cs. FIG. 16 shows a minimal pad approach employing a sandwiched layer with a conducting surface in the middle. Only one C_{S} and only one capacitive sensing circuit are required, although analogue switches (possibly inside the IC) will be required. Every slider section will require its own pad to be connected to the A side of the slider section.

This means a four section slider (i.e. 4 rows and n columns or 4 columns and n rows) can be handled by 4 pads (connected to A) and 2 decoding outputs. The n denotes the multiple points on a one dimensional slider that can be discriminated using the sensor. (External decoding would be required to connect one slider section at a time to the dummy load). n can be 4, 8, 10 or even 20 depending on the design of the circuit, giving a great number of keys with only limited IC size. An eight section slider will in this construction require 8 pads connected to the A side and 3 decoding outputs. The analogue switches can be implemented off-chip meaning the single sense channel pad (C_{X1}) will be required and the necessary binary coded number of outputs to drive the selection. For example, an eight section slider structure then requires (C_{X}) plus 3 decoding bits (A side) and 3 decoding bits (B side).

In another approach, all B contacts are connected together after passing through a diode, and then are connected through a single switch to the dummy load (FIG. 16). As such a four section slider with a single sense channel and analogue switches on-chip would require only 4 pads (on the A side) and a single pad to connect the B side to the dummy load when required. It should be noted that the capacitance of the external diodes connected to the B side must be taken into account when the circuit is designed and when components are chosen. The effect of the diodes in the discharging path (B side) must be countered on the A side, possibly by using a similarly modelled diode on-chip in the circuit as well.

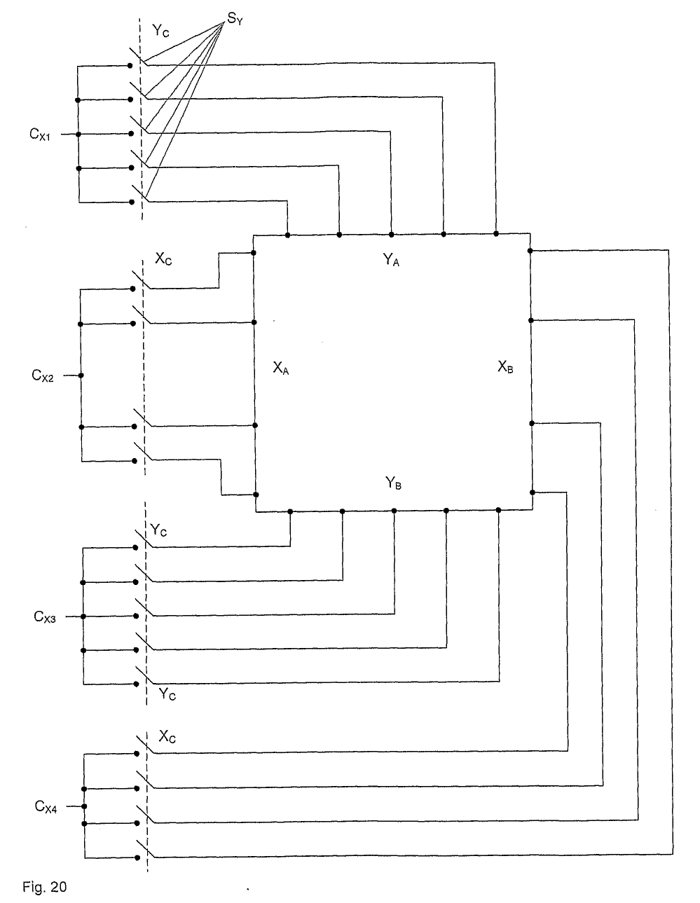

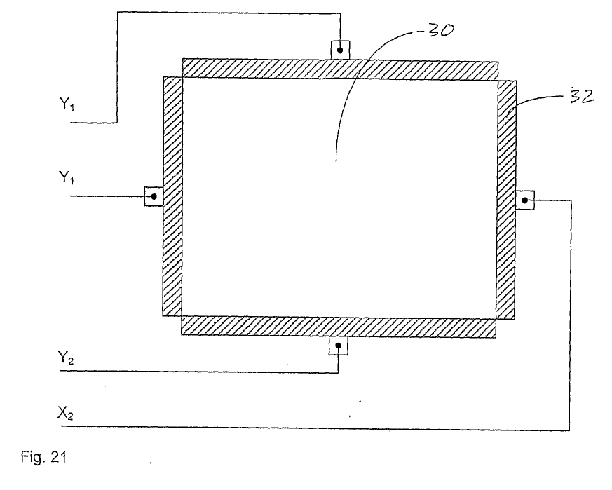

In a further embodiment the diodes on the B side may be removed at the expense of requiring additional pads. In this way each slider is connected through its own pads to the IC with internal switches selecting the slider connected to the dummy load at a time. (see FIG. 20 for a two-dimensional plate that can be viewed as a combination of two one-dimensional sliders).

An inherently non-linear measurement can be achieved by varying the resistive values in the sliders (for example FIGS. 1, 2 and 3). The same effect can be achieved with an uneven or irregular resistance per area, for example in FIGS. 4a and 4b.

The electrically conductive surface of the pad or slider can be insulated from the user or touch instrument (e.g. finger or conducting stylus) as long as the capacitive coupling through the insulating material (forming a dielectric layer) is sufficient.

It will be clear to a reader skilled in the art that the resolution obtained from this proposed structure can be very high. For typical charge transfer counts of 4000 to 5000, as is commonly achieved with the Azoteq IQS117 or IQS120, 123 or 125 products that register a difference of 800 or 1000 on a human touch, the same count (800 to 1000) can be the differentiation from one side of the pad (X₁) to the other side (X₂). Depending on the noise level in the system (e.g. if below 6 transfers) then 1000 divided by 20 (6 noise plus 14 safety margin), indicates that 50 pads can be handled. Clearly handling 50 pads in a coded digital approach will require a substantial number of sensing channels i.e. higher costs.

The cost and complexity to achieve such resolution or to sense this number of pads using a more digital approach with a sequence of pads each connected to a sensor in a coded format, would be substantially more. Even the complexity and cost of manufacturing the discrete pads would be substantially higher than, for example, a surface with an evenly distributed electrical resistance—see for example the pad formed in FIG. 2a where an evenly distributed resistor can be deposited in sections, or insulated sections can be formed by using, for example, cutting techniques such as grinding or laser cutting.

The slider structure can be divided into imaginary or notional areas and each area can be designated to be a specific button. This can be totally software configurable e.g. for the areas A, B and C in FIG. 4a. In some embodiments it may be advantageous to define dead bands or safety zones between such areas as D. This would enable a user to select A, B or C more distinctly. A crossover touch (touching zone D) can be ignored or a warning can be given.

The surface material can be compressible to assist in determining the pressure of a press. A light press on A and/or even a mere proximity event can be used to create a backlighting effect behind A or some other indication that A is being influenced or targeted. For example, an LCD unit may inform the user by flashing a value indicative of the position where proximity is sensed, or general backlighting may be activated. However, this type of indication will only be selected permanently with a hard press. Another way to differentiate between a provisional press and a definite selection is a “double tap” method. In this way a single touch would not result in the selection (as with a conventional switch press) but two consecutive touches will be required to make a selection. A single touch may be used to give an indication of the specific “button” as discussed above.

The pad in FIG. 4b can be divided into a matrix of zones (FIGS. 4c and 4d). Clearly any key or format could be chosen. The choice is only limited by the resolution and performance achieved as well as normal practical stylus operation, speed required, electrical noise etc.

To further reduce cost and complexity of the capacitive sensing device it is proposed that for a slider only one sensing structure is required.

In FIG. 4a X₁ and X₂ are each connected to a sensing channel doing charge transfer in a synchronous way to separate reference capacitors (C_{S}). The number of transfer cycles and specifically the differences when a proximity/touch is sensed, are then used to determine the position of the touch.

### Reduced Resources Required

Consider a design in which only one reference capacitor (C_{S}) is used. The charge transfers are done first from one side (say X₁) and then from the other side (X₂). It is important that the application charging times etc. are such that only limited movement can occur in the period of the two charge/discharge cycles taking place. Clearly by using analogue switches this can be handled through a single sense channel.

During the time that X₁ is sensed it is important to connect X₂ to a dummy load to get a diversion in the current to reflect the ratio of resistance between the point of touch and respectively X₁ and X₂. For example, if T is the point of touch in FIG. 4a then the ratio of R_{S1} to R_{S2} will be used to determine the point of touch.

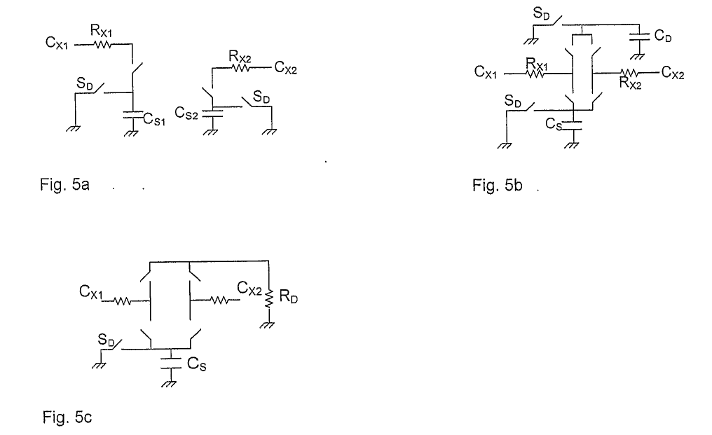

It is important, during the time that X₁ is measured by charging the plate and then discharging it into C_{S} (see FIG. 5b which shows a one channel arrangement), that X₂ is connected to create a discharge route for the charge from the sensed object (for example user finger/body). X₂ can be connected to a dummy capacitor i.e. a capacitor that is not sensed for measuring the change in capacitance, or it can be a resistance R, as a dummy load, connected to ground as is shown in FIG. 5c.

When using R connected to ground the voltage level in the dummy load will not rise as when using a capacitor. As such, the discharge to the dummy route will rise disproportionately when the voltage in C_{S} becomes higher. This may result in some non-linearity of measurements that must be compensated for when determining the position of touch. A trip level that is low with reference to the level of charging the sense plate will also reduce the effect of this voltage difference on the measured results.

During the time X₂ is measured, X₁ must be handled the same way (i.e. connected to a dummy load). The method of charge transfer capacitance measurement is well documented (see U.S. Pat. No. 7,148,704 B2, Dec. 12, 2006).

It follows that the same single input method can be used to measure a second dimension (FIG. 4b). If movement is too fast then response time and accuracy can be affected. Smoothing algorithms can be implemented in software to reduce the effect.

For point contact applications, for example where a finger is used to touch a key on a keypad, the timing should not play a role since contact is made over a relatively long period and the various dimensional measurements can be combined with any suitable de-bouncing mechanisms to minimize the additional time required to determine the position of touch.

In FIGS. 5a (which shows a two channel arrangement), 5b and 5c the switches S_{D} are used to discharge the reference and/or dummy capacitor (if used) between charge transfer cycles.

In FIGS. 4a and 4b the resistors R_{X} are external to the IC and plate structure. These resistors can help with ESD protection and insulation and can be implemented on-chip or off-chip, as well as being the representation of the total resistance added to the circuit due to various elements such as the pads, ESD structures, transfer switches etc.

Neither the one-channel nor the two-channel per dimension implementation handles dual or multiple point touch situations well. This is a definite factor to consider when deciding on how to implement a slider or key pad. However, a multipoint touch can be identified with some methods measuring the resistance across the slider to the touch position on both sides and this can be used to indicate an error condition, or to select a special function.

If multiple keys must be simultaneously registered on a keypad, then more channels are required. However, it would be possible to set reasonable levels in order to ignore two or more simultaneous touches on a keyboard or slider.

The teachings above clearly hold advantages for implementing touch pads for keys in applications such as keypads or keyboards on transparent and other materials such as glass, Perspex, nylon, plastics etc. with a uniform electrically conductive surface, without requiring numerous tracks to crisscross the surface. For a 2 dimensional pad insulation regions may be required, see FIGS. 4b and 2b.

It is possible to envisage a screen of a mobile phone, GPS unit or other electronic-based consumer product like e.g. a mp3/4 player, microwave oven, washing machine etc., being the full keyboard for user data and/or user command entry. The keys/buttons are shown with, but not limited to, back lighting, LED's, LCD and/or light pipe technology. In fact, the buttons can be switched on and off at will or can even be changed and repositioned in software.

In a screen based product (e.g. GPS for route navigation) the screen may be fully functional with the desired display (e.g. GPS showing streets and other navigational information) with the buttons not displayed. However, upon detecting the proximity of an object (e.g. user hand) the display would bring up the various touch button options. This may then impact on the display and reduce the display size. Exactly the same approach can be taken with a TV display where the TV picture can be reduced and information displayed on a section of the display about the specific button to be targeted or button positions, settings etc. This display partitioning can be triggered by a proximity event or a touch event. Clearly the same effect can be achieved with the buttons implemented on a structure around or on any side of the display. The display may then indicate the functions or selections attached to or associated with such buttons. As disclosed above, the display of button related information on the screen may at least be triggered when a proximity or touch event is detected by the capacitive sensing structure.

In a product with multiple buttons or switches a proximity event may cause a general backlighting to be activated but with specific areas, more likely buttons to be used next, being shown more pronounced.

In a vehicle a heads-up display or command entry, touch pad-based system can be implemented on the front windscreen. The visuals would become visible upon detection of a proximity detection event or a touch detection event. For example, the top of a windscreen in front of a driver can be used for command entry to select functions such as, but not limited to, speed control, GPS commands or mobile phone operation. Selections and settings can be made directly on a graphical user interface (GUI). A fault condition indicator can be further interrogated by directly pressing on transparent material covering the fault indicator.

Side windows can be controlled with controls directly on the window.

A significant benefit of the invention lies in the cost effectiveness and ergonomic implementation made possible by the low pin count and interface connections required, and the scope these features open for command entry devices where the touch pad for a sensing system is structurally integral with the product housing it is part of.

An alarm activation/deactivation keypad for a house, vehicle etc. may be part of a glass door, or a piece of glass that will act as the keypad can be attached on an inner side of a bigger glass door or window. There is then no need for a weatherproof keypad unit that must be installed at substantial cost at an outside accessible place. For the special glass with an electrically conductive surface it may be possible to cut insulating lines to define a keypad of any particular shape. It is possible to link pads with normal surface mount type resistors using conductive glue or a solder paste type substance. Even LED's can be placed directly onto a glass surface.

Applications such as in an aircraft, bus or train window, wherein the window itself forms the keypad for user input, can be practically implemented. This is almost in the form of a heads-up display but featuring input functionality as well,

### Auto Calibration

Another matter of importance is the handling of calibration or auto calibration to ensure continued or initial accurate sensing when a device is powered up. This auto calibration may even be limited to a one time event during commissioning or testing of the device. The auto calibration can emulate a touch or proximity event without requiring a user touch or proximity to perform the calibration.

The calibration capacitance/resistance is used as a substitute for an external “touch” that is under control of a microchip. However, for this approach to work with a minimum number of IC pads/pins, the resistors R₁ and R₂, if required at all, must preferably be implemented on-chip.

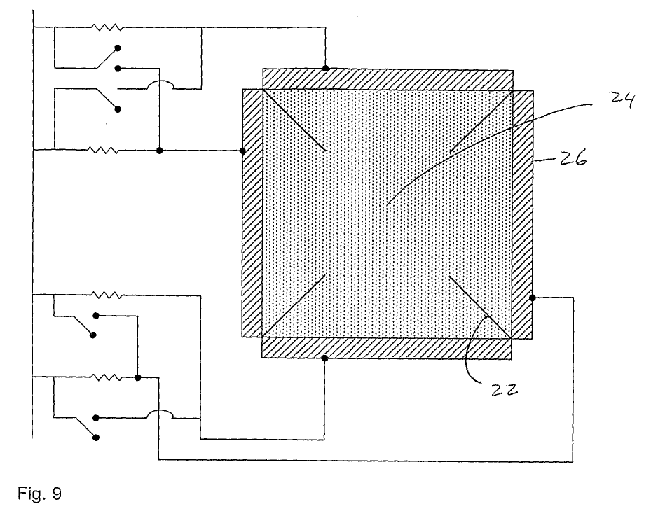

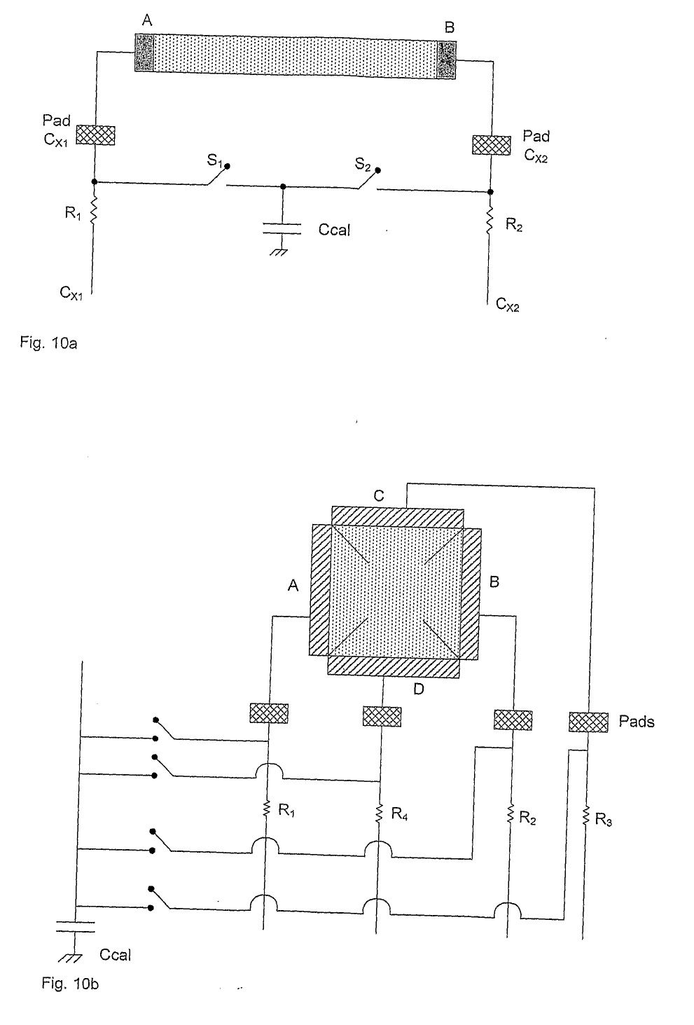

FIGS. 10a (which shows auto calibration for a slider) and 10b (which shows auto calibration for a two dimensional system) illustrate a layout in which a capacitor Ccal is connected, in turn, effectively to one side of the slider at a time. FIGS. 8 and 9 show circuits wherein the pad capacitance of the IC is used to cross connect and thus create the effect of an object coupling with the various sides of the slider or pad (e.g. sides A or B).

With this design, the Ccal value can be added to one end of the slider and then to the other by closing S₁ and S₂. Ccal can be a dedicated capacitor (on-chip or off-chip) or can be part of a pad structure.

With S₁ closed the effect of the capacitance Ccal can be measured on C_{X1} and C_{X2}, emulating a touch at A. An S₂ closure will emulate a touch at B. The effect of Ccal (i.e. the charge transferred to C_{S} in every charge/discharge cycle) can be replaced with a Rcal coupled to the charging voltage (preferably the regulated V+). It may be easier to implement the Rcal on a silicon substrate than the Ccal, yielding a better integrated and less costly solution. For example, it might have been necessary to use a pad and external C if 15 pF is required but depending on the charge time from Rcal to C_{S} every cycle (say it is for example 1 usec) it is possible to have Rcal in a reasonable range (100 kOhm to 200 kOhm) designed and laid out in a normal CMOS process that will have a similar charge transferred to C_{S} as from Ccal to C_{S}.

For auto calibration the following actions are required—a measurement with side B floating; a measurement with B connected to a dummy load with Ccal or Rcal emulating a touch at side A; and a measurement with side B connected to the same dummy load and with Coal or Rcal connected to side B.

### Cross Bleeding

When implementing a slider with the limited sense channels approach, a situation may arise in which the C_{S} capacitors may bleed into each other and thus reduce the difference in the number of charge transfers between the two channels caused by the resistance divider. If the method of implementing a single C_{X} and C_{S} per slider is used and one side is grounded through a dummy R, then C_{S} can easily bleed to ground.

In each charge/discharge cycle the touch capacitor (C_{T}) is discharged into C_{S1} and C_{S2} through the dividing network R₁+R_{S1} and R_{S2}+R_{S2}. The discharge happens when S₁ and S₂ (see FIG. 11) are closed. If one capacitor, e.g. C_{S1}, charges faster than the other, C_{S2} it can happen that C_{S1} will actually discharge through R₁+R_{S}+R₂ to C_{S2} for some periods. This is especially true for low resistance values.

In order to prevent this it is suggested to add a blocking mechanism (e.g. diodes or to open the switches before cross bleeding can start) to the discharge paths either off-chip but preferably on-chip (see FIG. 12). Adding diodes means the charging of the sense plate (and C_{T} when a touch occurs) must be done through a different pad, if for example diodes are off-chip, either as is shown in FIG. 12, or with switches bypassing the diodes D₁ and D₂.

When done internally to the IC it is possible to minimize the pad capacitance which is advantageous to the resolution and sensitivity that can be attained. The diodes D_{C1} and D_{C2} will add capacitance to the sense channels if used.

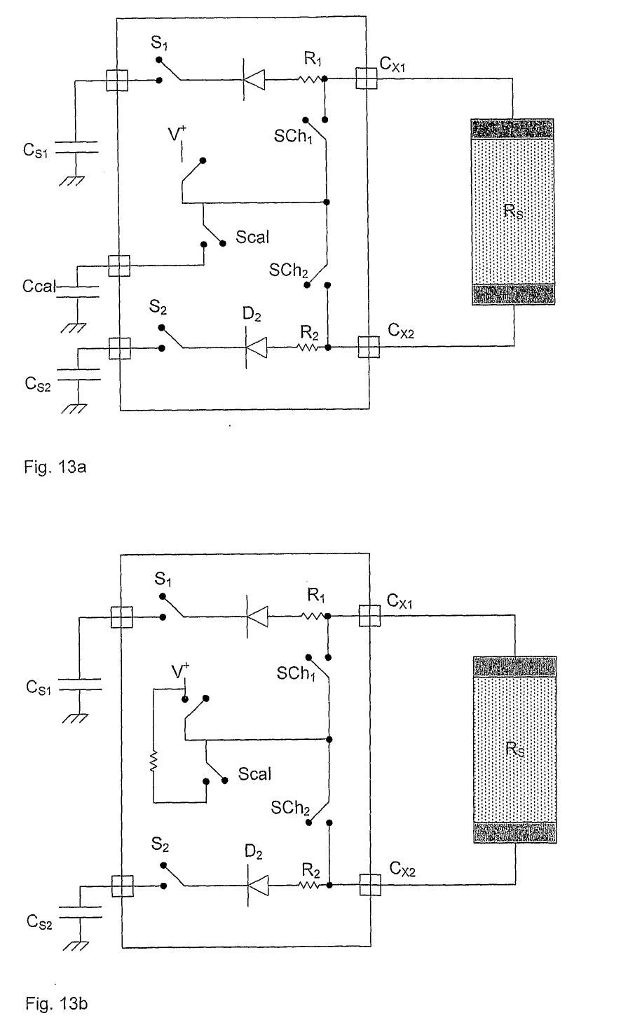

With a sequence of switching the charging switches SCh₁ and SCh₂ (FIG. 13) such that they are not always closed at the same time, the normal charging and discharging cycles can be performed to do the capacitive sensing but any cross bleeding can be prevented. During the charging cycle the switches can be closed at the same time. The same blocking effect can for example be achieved by sensing the current through S₁ and S₂ and opening S₁ or S₂ the moment the current flows from the C_{S} direction towards R_{S}.

FIG. 13a shows an example of a structure wherein cross bleeding is prevented and Ccal is used for auto calibration. This structure can also be combined with the auto-calibration structures to yield a well integrated solution: see switches Scal and S₊ (for charging) in FIG. 13b in which Rcal is used for auto calibration

The resistances R₁ and R₂ can be purposefully inserted for ESD purposes and may also represent the switch resistance of S₁ and S₂. In FIG. 14 the dummy load is shown as an on-chip resistor. This may be easier or less costly to implement on silicon. However, this resistor (or a capacitor) may also be conveniently implemented off-chip.

In another embodiment to prevent cross bleeding and improve the dependency of the measurements on the ratio of resistances formed in the interface structure, a trip level is set at a level below Vdd/2 (less than half the voltage to which the Ct is charged). A check is then performed on the inputs from the slider to the IC and if the voltage at that point drops to below Vdd/2, the discharging is halted on both sides of the slider. This will conveniently prevent cross bleeding as well as assure equal timed discharging for both sides of the slider.

In a further embodiment of slider (one dimensional) or pad (two dimensional) touch/proximity position sensing, it is possible to sense only on one channel per dimension during normal operation. When the 2 sense channel method shown in FIGS. 6a and 11 is used the measurements in FIG. 7 are obtained. Essentially a gradient must be determined (what will the measurements be for a touch at one extreme of the slider (A) and for a touch at the other extreme (B)), as well as the value of the touch capacitor (Ctouch). The sum of the measurements through C_{X1} and C_{X2} is a good indication of the value of Ctouch.

If the gradient for the specific slider or pad is known and if the Ctouch value is known from the sum of C_{X1} value plus C_{X2} value, then the position on the slope is known from either the C_{X1} value or the C_{X2} value and thus the position of the touch on the slider can be calculated.

However, the value of Ctouch can also be determined by a capacitive measurement at C_{X1} when B is left floating i.e. electrically insulated. This is because all charge from Ctouch will be discharged through C_{X1} as there is no divider to conduct part of the charge to, for example, the C_{X2} channel. Care must be taken that Ctouch is fully charged/discharged irrespective of where on the slider the capacitive coupling is made, and the capacitance of the pad must be limited with respect to the C_{T} and sense plate capacitance. As such in some embodiments it may still be better to charge at both sides of the slider (A, B) but measure only C_{X}, with B in effect floating. This will depend on the RC time constants of the circuit being in good relation to the CD (charge/discharge) cycle frequency, i.e. the time constant must be short enough to ensure that Ctouch is fully charged and discharged every (charge/discharge) CD cycle, irrespective of where on the slider/pad the touch occurs.

Once a touch event is recognized, a charge/discharge (CD) cycle is done with B connected to a dummy load. During the time waiting for a touch to occur, only the measurements with B open need to be done. The dummy load is needed to create the same divider structure as was the case when the slider was measured through two channels (A, B) as described above. It may be possible to have a simple dummy load (R or C connected to ground), a C with a parallel (bleeding) R to ground, or even a similar capacitor structure as C_{S1}.

With the dummy load connected to B the measurement on C_{X1} will in effect yield the same result as above in the two channel approach, i.e. a value of change in charge/discharge cycles (compared with the B floating value) that is related to the position of the Ctouch coupling with the slider structure. With this the same information is available from a single channel measurement as was obtained from the dual channel approach and the position of touch on the slider can be determined in the same way.

In another embodiment of the single sense channel implementation of determining a touch position on a 1D slider, the voltage on the dummy load is controlled to match the voltage on the reference capacitor (Cs) of the sensing channel that is connected to the A side of the slider (see FIG. 6b). Significant advantages in terms of preventing cross bleeding, equal timed discharging and reducing the effect of different discharge rates due to voltage differences on the two sides are gained through this implementation. This works towards having the discharge into the reference capacitor from Ct being purely dependent on the ratio of resistances formed in the slider based on the point of touch.

Clearly two consecutive measurements are required (one with B floating and one with B connected to a dummy load) to determine the touch position on the slider. If the movement on the slider is such that the Ctouch value varies between these measurements, then inaccuracies may result. However, it is possible to do smoothing in software to handle Ctouch values (B open) on both sides of the measurement when B is connected to a dummy load. Changes which are too large may also warrant discarding a measurement. It is favourable that the action is a sliding action and essentially is performed with constant pressure which is different from pressing individual buttons where every press starts with a light touch, increasing in pressure until a maximum is reached and then the reverse action occurs. A constant value of C_{T} means that every measurement with B connected to the dummy load is completely standalone in terms of reflecting the position on the slider where the touch was made. It is to be noted that the touch event need not be an electrical contact event, but only needs to be a capacitive coupling of sufficient nature.

FIG. 15 shows practical results measured with 1 kOhm between pads and a 100 kOhm dummy load connected to ground. As can be seen the measurements show great stability and linearity for clear identification of the pads touched.

In order to improve performance and practical operation, trip events (proximity or touch) may be noted that do not comply with the debounce requirements, or where no event is registered shortly thereafter that meets the debounce requirements. Such an event is then viewed as a false trip. A second order filter (or other adjustment mechanism or filter) may be implemented which will be adjusted in the case of false trips to aid the use of a long term average (LTA). The LTA is a value derived from current measurement values forming an average that drifts up or down as the environment changes. The new value may be denoted as a long term noise average parameter. If the LTA is stable and events are often detected that do not continue into real proximity or touch event detections, the long term noise (LTN) parameter is increased at a specific rate to be determined for a specific application. This value then effectively increases the trip level. However the LTN parameter is more a measure of the noise level than the average of the number of charge transfer cycles required for a specific implementation. As such the LTN factor is independent of the LTA value.

In a further embodiment the LTN average parameter may also be adjusted when a valid proximity detection is made but thereafter no touch event takes place. If this takes place in an application where, for example, proximity is used to activate backlighting for buttons that must be touched or otherwise activated, then regular proximity events with no follow through of button activation will likely be an indication of a false trip. If these events are in a situation where regular proximity triggers are detected but do not meet debounce conditions, a strong likelihood exists that false triggers are being generated. Each event may add to the LTN parameter through some coefficient and the coefficient may be increased when both conditions (proximity levels without meeting debounce requirements, as well as proximity events without touch events following) are met.

In a further enhancement of this solution for dealing with noise related false trips or event determination, the LTN is reduced over time. This can be a very slow process and in some cases is halted at zero. I.e. the trip level is not at the most sensitive level possible. However, it is also suggested that in some embodiments it is possible for the LTN parameter to become less than zero resulting in a lower trip level. The design must be such that this only happens in a low noise environment.

The structure above is very powerful and advantageous in cases where proximity and touch events are detected by the same sensing circuit, and specifically also when proximity events are only used for non-critical events like activating backlighting but not permanently switching on products or permanently selecting functions. Use of this structure is however not limited to these situations.

In two dimensional structure touch position determinations it is proposed that one or two channel approaches for the one dimensional slider can be extended to two (or possibly three) dimensional sense pads in the following ways:

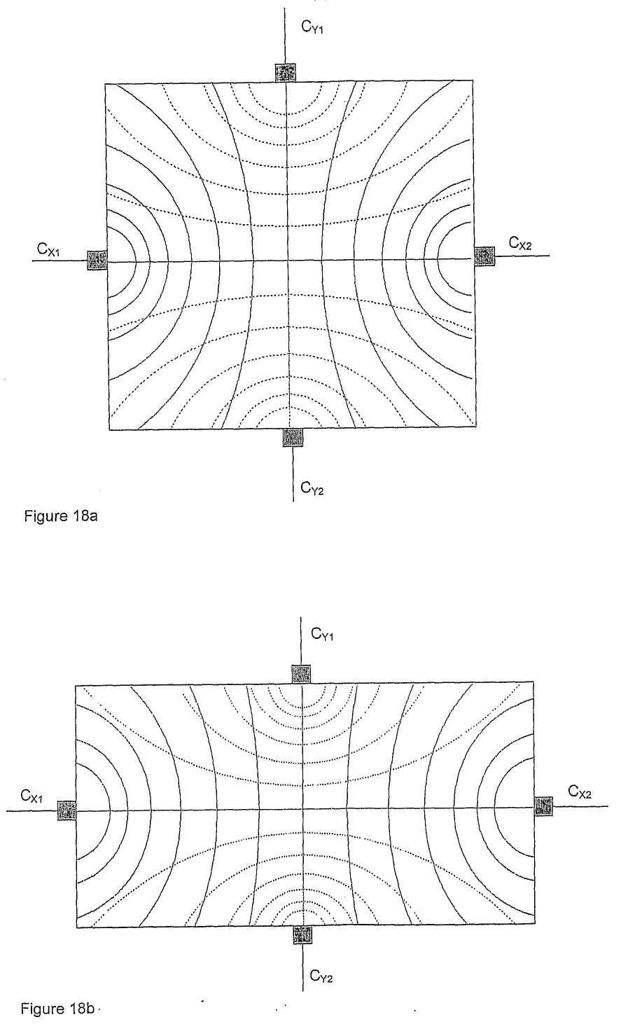

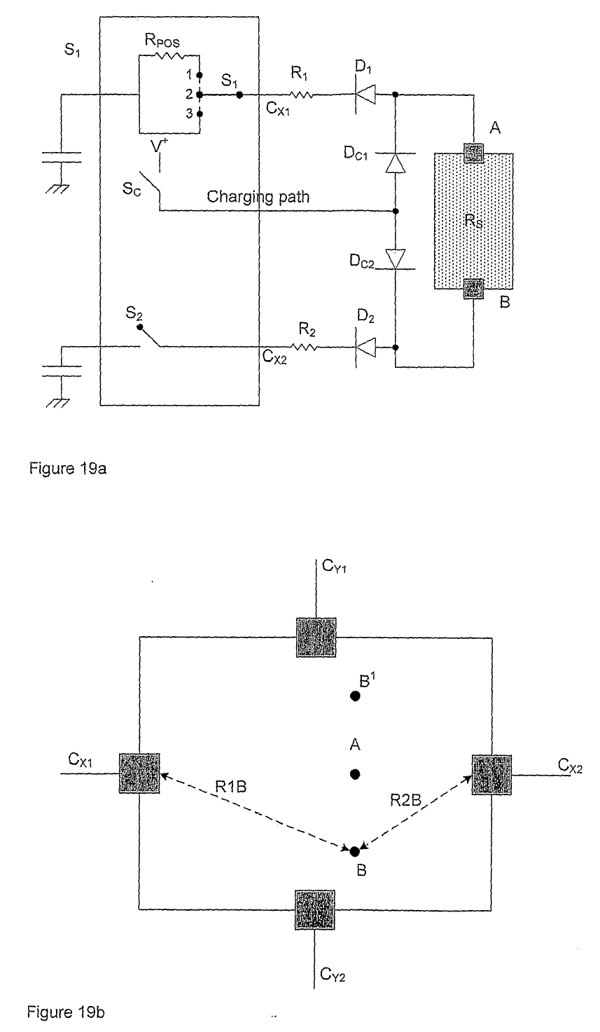

Firstly, in a method that is appropriate for a single sense channel (or two) per dimension, it is proposed that the sensors are connected to the sense pad or plate as per FIG. 17. Since the sensing circuit measures the ratio of the resistances from the touch position to the two connection points, the ratio of specific values of RX1/RX2 lies on a specific curve (see FIGS. 18a and 18b).

Thus, measuring in only one dimension gives an indeterminate value as the value can indicate any position on a curve. However, when the other dimension is also measured and the curves are superimposed it is clear that a good positional determination can be made from the two measurements.

If more accuracy is required, specifically in the corners, further diagonally positioned measurement points or combinations of the existing sense channels or dummy loads, can be employed when required.

Secondly, the determination of a position of a touch on a two dimensional sense plate can be improved by adding a known resistance to selected measurements—see FIG. 19a. Effectively a ratio of the resistance from the touch position to the sensors on both sides, is determined. Then a known resistance is added to one side in the sense channel and by using the new ratio that is determined in conjunction with the first, it is possible to determine more precisely where the touch occurred.

The following formulas allow for a more accurate calculation of the position in the two dimensional axis. If done for both X and Y dimensions a more accurate position of the touch can be determined. For the normal CT (charge transfer) operations the ratio of R1B and R2B in FIG. 19b is determined. It is also possible to determine the value of R1B+R2B for a specific slider. This can be done during setup calibration or continuously during normal operation. There is a point A that is in the direct line between Cx1 and Cx2 with the same ratio value as for B i.e. R1a/R2a=R1B/R2B. The total value of R1a+R2a is smaller than R1B+R2B.

Without the Rpos (FIG. 19a) assume P1 is the ratio of R1B/R2B, i.e.

P1=R1B/R2B

Then with Rpos in the circuit:

P2=(R1B+Rpos)/R2B

This can be resolved as:

P1.R1B=P2.R1B+P2.Rpos

R1B(P1−P2)=P2.Rpos

R1B=(P2.Rpos)/(P1−P2)

Since P1 and P2 are the measured ratios and Rpos is known, the value of R1B and thus of R2B can be calculated and an accurate determination of the position B (and B¹) can be made.

A point B¹ exists that has the same values as B, but in a mirror position, as shown in FIG. 19b, and to resolve this ambiguity the other dimension must be measured as well.

FIG. 20 shows an embodiment to determine a position on a grid using capacitive sensing circuitry. A two-dimensional plate e.g. of glass is covered on one side with a uniformly resistive coat or layer. The plate has multiple contacts per side. All the lines connected to each side are connected to switches S_{y}. The switches are controlled by control signals, namely Y_{c} for the top and bottom sides YA and YB and X_{c} for the vertical sides XA and XB. On the other side of the switches the lines can be combined into one or more lines which are connected to a respective capacitive sensing channel C_{X1} to C_{X4}. The switch for one line, on each side, may be omitted.

The arrangement is such that all the switches in one dimension are open when the other dimension is being sensed for a touch position. In principle each of the two dimensions can be treated as a one-dimensional slider. When the vertical dimension is being sensed the channels C_{X1} and C_{X3} are operational and the switches S_{y} are closed by means of the control signal Y_{c}, During this time the switches controlled by the signal X_{c} are open and the channels C_{X2} and C_{X4} are not operational. In further embodiments each switch can be individually controlled.

Each of the switches has a capacitance that is added to the capacitance of each sensing channel. The capacitance of each bonding pad, ESD structure and of each other part such as pcb tracks etc. is also added to the capacitance of the respective sensing channel. The sum of these capacitances is referred to as a parasitic capacitance, the presence of which is not desirable. It is possible to cancel the parasitic capacitance by inserting effectively a negative capacitance of the same value into the circuit. For example, a similar sized capacitor can be charged to an equivalent but negative voltage and coupled to the reference capacitor C_{S}. The objective in this regard is to negate the flow of charge from the parasitic capacitor in order to measure the capacitance of the sense plate and, in particular, any change that may occur. This applies to all known parasitic capacitances (C_{R}) in the circuit. The value of the parasitic capacitance in the circuit with the open switches can also be reduced with a driven shield approach.

This structure overcomes the problem encountered for example in the FIG. 4b embodiment which requires the making of diagonal cuts into the conductive material. This is, however, at the expense of the extra lines and switches.

The connections per side can be linearly spaced. However with a non-linear spacing (e.g. the connections can be further apart close to the centre of each side) fewer lines can be used but the same performance can possibly be achieved.

If all the switches were closed the X dimension connections would create a short circuit on the sides when the Y dimension is measured and vice versa.

FIG. 21 shows an embodiment of the invention for determining a position on a grid wherein the two dimensional terminal plate is covered with a uniform resistive layer 30 with a termination structure near each side, or the plate itself is constructed to have a resistive value of R ohms per unit area. The sides of plate are terminated with a resistive strip 32 to help eliminate or reduce the border effect. If an appropriate termination is implemented the number of lines per side can ideally be reduced to one line per side connected to one capacitive sensing channel per side. The termination strip can be formed by attaching a strip with resistance R_{T} ohms per unit area to the plate (see Keefer et al—U.S. Pat. No. 7,327,352, Pepper jr—U.S. Pat. No. 4,371,746, U.S. Pat. No. 4,198,539, U.S. Pat. No. 4,293,734).

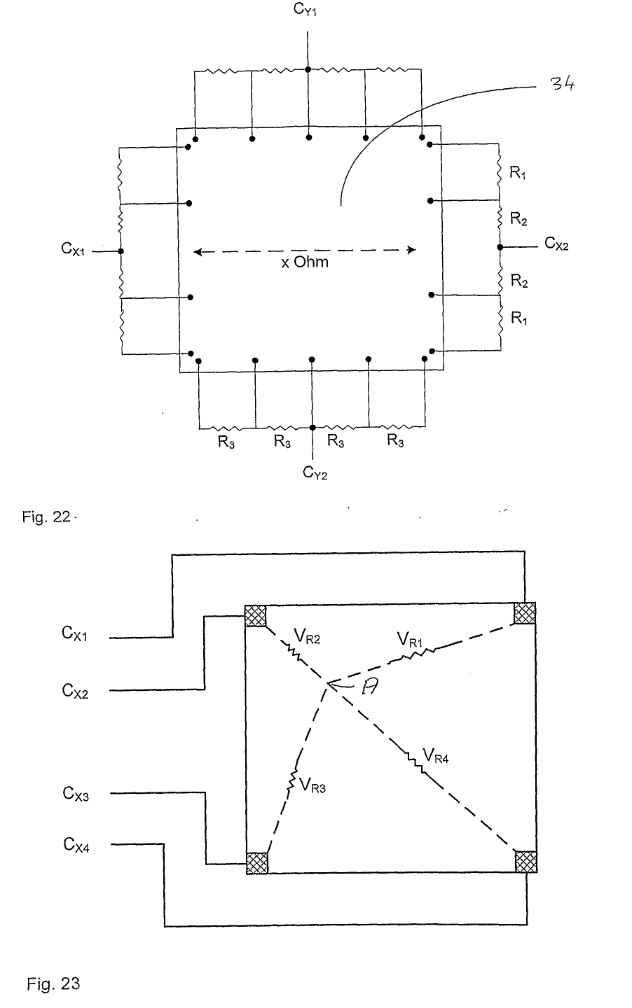

FIG. 22 shows another embodiment for determining a touch position on a grid using capacitor sensing in a dimensional approach with the termination of the uniformly resistive layer/coat/structure 34 of the plate.

This structure is a simplified implementation of the “analogue” approach adopted to terminate the resistive structure. Contacts of each side are connected through a resistive structure.

An uneven number of connections could possibly work better in terms of the single value. If the connection points to the plate are not evenly spread the values of the resistors will have to be adjusted accordingly. In this way the switches of FIG. 20 can be removed and this substantially reduces or eliminates the capacitance that is otherwise added to each input (bonding pad etc.) and output. Also, pads in the corners may be shared to reduce the number of contacts as well as the number of pads required on the IC.

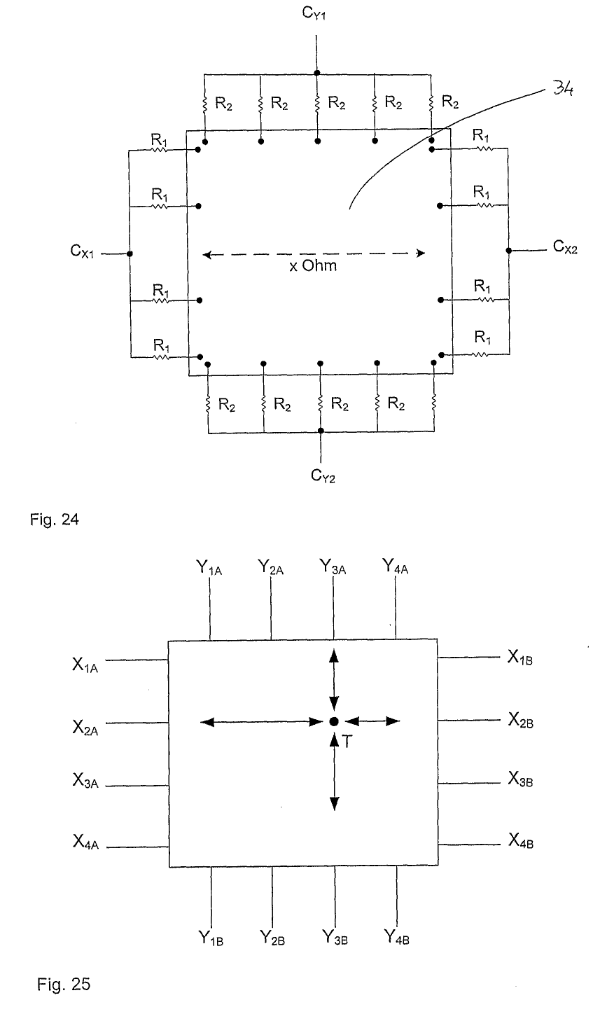

In a further embodiment (FIG. 24) the resistances at each end are terminated in a star configuration. The requirement is that the resistances must be as small as possible, but the resistance of the two connections the furthest apart on each side must be comparable with the resistance in the same dimension of the plate itself i.e. if the resistance in each line is R then 2R must be comparable to the resistance of the plate in that dimension.

In a further embodiment four capacitive sensing channels are employed and are all sensed at the same time. If a capacitance is coupled to a point A then from this point A four virtual resistances are formed to the connections of the four channels to the sense plate (V_{R1} . . . V_{R4}) (see FIG. 23). The charge flowing from the capacitor coupled at A would divide according to these resistances when flowing to the channels C_{X1} to C_{X4}. It is clear from earlier discussions relating to the two dimensional slider that this would enable the calculation of the geometrical position of A on the plate.

In order to reduce the effect of parasitic capacitance it is proposed that the capacitive sensing circuit performs a self-calibration routine to set the remaining capacitance of the sense plate (pad, antenna, grid etc) at a specific value for which the system is designed i.e. if a known reference capacitor of, say, 50 nF is placed in the circuit and a sense plate of 10 pF is required, then negative capacitance can be added until the required number of transfers results from the charge transfer process. This means that a more predictable effect and performance can be achieved by a touch event (e.g. human or proximity event) because the sense plate and all parasitic capacitance have now been tuned to a predetermined value.

This negative capacitance can be implemented in various ways. Known technology in the art, for example negative impedance converters, (NIC's) can be used to implement a negative capacitor (see Negative-Impedance Converters by A Larky, IRE Transactions on Circuit Theory, Volume 4, Issue:3 Sep. 1957, pages 124-131). Another possibility is to add a capacitor C_{X} on the IC that is parallel to the reference capacitor (C_{S}). However this capacitor is discharged to ground each cycle when the sense capacitor C_{X} is discharged into the C_{S} capacitor. In an adaptive embodiment the discharge of this tuning capacitor (Ct) is adjusted until the number of transfers in the charge transfer cycle reflects the desired value for the sense plate.

It may be advantageous or even required to use active driven shields to protect the lines coming from each side of the two dimensional plate from parasitic capacitive coupling with the external world. An example of such unwanted coupling is when the apparatus is designed to monitor a user's fingertip touching the plate, but in the process the user's whole hand comes close and thus influences one side of the plate more than the other sides.

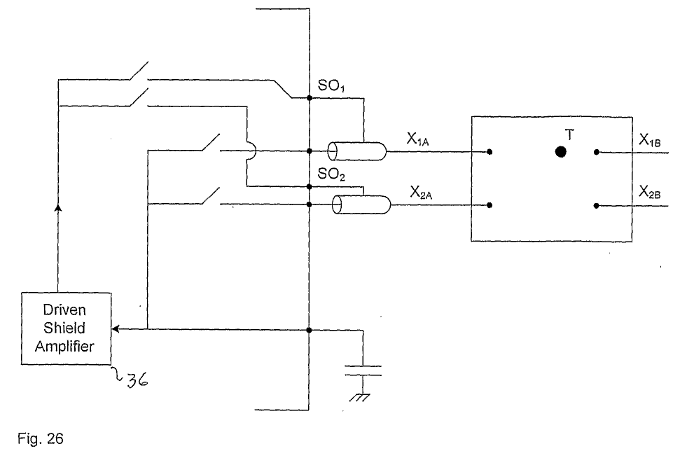

Ideally every C_{X} contact to the sense plate must have its own shield and hence two nodes is relevant i.e. an input to the driven shield 36 and a driven shield output. For a two dimensional system with four contact points to each side of the sense plate this means 32 nodes/pads. In an effort to reduce this (to save cost, space and complexity) the inputs may all be derived from a node on the circuit taking each line into the IC. (FIG. 26 shows a possible circuit for selective driven shield activation). This still means 16 shield output lines and hence 16 shield amplifiers, 16 output pads etc.

In the embodiment using the resistive structure to combine the lines on each side (see FIG. 24) it is possible to use the point where they come together as the shield input. Obviously some part of the lines will not be as well shielded as with individual shield structure, but this will reduce the requirements to shield four output lines and possibly four input lines. If the shield input is now derived from a node inside the IC it means only four outputs are required.

In the embodiment of using switches to connect to multiple points on each side of the 2 dimensional plate (see FIG. 20) it is required that each switch be individually controlled. This means when the X dimension is measured all switches on a side may be closed or only a selected group (preferably just one) may be closed. Only the switches that are closed conducts charge from the proximate object to the C_{X} inputs. In order to improve accuracy of the shielding operation without undue hardware requirements it is suggested that when measuring the X dimension this information is then used to decide which of the Y dimension switches must be closed for optimum operation—see FIG. 25. Then clearly in the next measurement the information of the Y measurement may be used to decide which switches of the X dimension must be used for the subsequent X dimension measurement. For example the sequence starting from a no-touch condition may be as follows:
(a) determine the position in a dimension—say in the X dimension of FIG. 25 using all the connected contacts to the sense plate (all switches closed);
(b) use the information gleaned from step (a) to determine which switches in Y dimension must be closed. Y3A and Y3B in the example of FIG. 25 are the switches that will yield the best results; and
(c) use the information from step (b) to determine which switches must be closed for the next X dimension measurement. Clearly in the example of FIG. 25 this will be X2A and X2B.

In some positions it may be beneficial to close two switches for measurement but it is suggested that generally it will be better to close only a single switch per side. This is then a dynamic process and as the finger moves across the two dimensional surface of the sense plate each previous measurement will determine which switch or switches to use in subsequent operations of measuring the next dimension.

The usage of selected switch closures may be advantageous on its own, but has a particular benefit when implementing driven shield structures for such two dimensional sense plates. In this case a single shield output may be used for each of the 4 sides of the sensor shielding each line from each contact point with the sensor individually. Without the selected switch closures all switches for a side will be closed when that dimension is measured. Since all points on the plate will conduct different charge it means that each will have its own waveform and clearly the single shield cannot follow each accurately. Hence the shield will add unwanted parasitic capacitance to the measurement. However, if only a single switch is closed the active driven shield only needs to produce that particular line's waveform on the shield output. All other shields on a side will still follow this waveform on the shield but since they are not closed the resulting negative impact will be limited.

When two switches must be closed it is argued that the waveform on each will be very similar, so the error is small and as such can be accepted. This is because closure of more than one switch need only be considered if the point of “touch” is between them. The moment it is clearly closer to (more in line with) one set of contacts, then only one switch needs be closed on each side. Since one dimension is measured at a time, only two shield outputs may suffice if further reductions are required. However, the input to the driven shield structure must be derived post the switches internal to the IC. In an embodiment where the switches are implemented on the same IC as the capacitive sensing circuitry, the requirement for effective shielding is now reduced to four or two outputs and two shield amplifier structures.

1. A capacitive sensing circuit for determining the position of an object proximate to, or in physical contact with, a sense plate, in one dimension of the sense plate which includes:
a charge transfer measurement channel connected to a first side of the sense plate,
with a second side of the sense plate connected to a dummy load during some charge transfer measurement cycles and during other measurement cycles the second side is not connected to the dummy load, and
wherein the sense plate includes a uniformly resistive element between the first and second sides of the sense plate.

2. The capacitive sensing circuit of claim 1, wherein the circuit is first used to determine a position of the object in one dimension of the sense plate and then in the other dimension, and wherein information from these determinations is then used to calculate a two dimensional position related to the sense plate.

3. The capacitive sensing circuit of claim 1, wherein multiple one dimensional sense plates are positioned in parallel next to each other but are electrically insulated from each other, and wherein measurements from the multiple sense plates, taken with the dummy load not connected, are used to determine a position in a dimension which is perpendicular to the parallel dimension of the sense plates.

4. The capacitive sensing circuit of claim 3, wherein the position which is determined influences the selection of the sense plates to be measured for determining the dimensional position of the object in the parallel dimension of the sense plates.

5. The capacitive sensing circuit of claim 1, wherein a voltage on the dummy load is regulated during the charge transfer cycles to follow the voltage of a reference capacitor in a measurement circuit.

6. The capacitive sensing circuit of claim 2, wherein a voltage on the dummy load is regulated during the charge transfer cycles to follow the voltage of a reference capacitor in a measurement circuit.

7. The capacitive sensing circuit of claim 3, wherein a voltage on the dummy load is regulated during the charge transfer cycles to follow the voltage of a reference capacitor in a measurement circuit.

8. The capacitive sensing circuit of claim 1, wherein a voltage on each side of the sense plate is monitored and if it drops below a predetermined level on either side, the discharge from the object is halted on both sides, before the next charge/discharge cycle, starting with the charging of the object, commences.

9. A capacitive sensing circuit for determining a two dimensional position, with reference to a sense plate, of an object proximate to or in physical contact with the sense plate, including at least a capacitive measurement circuit connected to at least one side of the sense plate in each dimension, wherein the sense plate includes a uniformly resistive element and wherein the circuit is implemented in accordance with at least one of the following configurations:
(a) the capacitive measurement circuit, connected to at least one side of the sense plate in each dimension, is connected to the sense plate with multiple contacts with a switch for each contact and wherein no more than one of said switches in a dimension is closed when a measurement is made in the other dimension;
(b) a dummy load is connected through at least one contact and switch to a side of the sense plate, that is not connected to a charge transfer measuring channel, in each dimension and wherein the at least one switch connecting the dummy load to the sense plate is closed during some measurements cycles and open during other measurements cycles; and
(c) at least two capacitive measurement circuits are connected to the sense plate in each dimension, one to each side, each measurement channel being connected with multiple contacts to the sense plate and a switch for each contact, and wherein no more than one of said switches per side in a dimension is closed when a capacitive measurement is made in the other dimension.

10. The capacitive sensing circuit of claim 9, wherein the circuit is implemented at least in accordance with 9a.

11. The capacitive sensing circuit of claim 9, wherein the circuit is implemented at least in accordance with 9b.

12. The capacitive sensing circuit of claim 9, wherein the circuit is implemented at least in accordance with 9c.

13. The capacitive sensing circuit of claim 10, wherein a dummy load is connected through at least one contact and switch to a side of the sense plate, that is not connected to a capacitive measurement circuit, in each dimension and wherein the dummy load is connected to the sense plate during some measurements but not connected to the sense plate during other measurements.

14. The capacitive sensing circuit of claim 13, wherein the voltage on the dummy load is regulated to follow the voltage on a reference capacitor in the capacitive measurement circuit during measurement cycles.

15. The capacitive sensing circuit of claim 11, wherein the position measurement of a previous dimension influences the selection of which contacts to the sense plate will be selectively connected to the sensing channel in a next measurement cycle of the other dimension.

16. The capacitive sensing circuit of claim 9, wherein the voltage on each side of the sense plate is monitored and if it drops below a predetermined level on either side, the charge transfer is halted on both sides before the process continues with the measurement cycle.

17. The capacitive sensing circuit of claim 9, wherein a capacitive cancellation technique is used to reduce the inherent capacitance associated with a sense plate.

18. The capacitive sensing circuit of claim 1 wherein the capacitive measurements are done with a charge transfer mechanism that involves a cycle of charging the sense plate and the discharging thereof into one or more reference capacitors until a predefined trip level is reached.

19. The capacitive sensing circuit of claim 1 wherein at least one driven shield is used to shield the connections to the sense plate.

20. The capacitive sensing circuit of claim 1 wherein determination of a proximity event is derived from a measurement taken with one side of the sense plate not connected to a discharging element.

21. The capacitive sensing circuit of claim 1 wherein a long term noise filter level is maintained based on fluctuations in the measurements, to automatically help select optimum trigger levels for deciding on proximity or touch events based on a delta between a current measurement and a long term average value that is calculated from a number of previous measurements.

22. The capacitive sensing circuit of claim 9, wherein the voltage on an element being discharged into, on a side of the sense plate, is regulated, during the charge transfer cycles, to follow the voltage of a reference capacitor in the measurement circuit.

23. The capacitive sensing circuit of claim 1, wherein the circuit is used in a heads-up display or glass window application to enable user selection of functions that are displayed.

24. A method of determining the position of an object, proximate to, or in physical contact with, a sense plate, in one dimension of the sense plate, which includes the steps of connecting a charge transfer measurement channel to a first side of the sense plate, and connecting a dummy load to a second side of the sense plate only during some charge transfer measurement cycles.

25. A method according to claim 24 which is used to determine the position of the object in a first dimension and then the position in a second dimension, and data relating to the two positions is used to calculate a two dimensional position of the object related to the sense plate.
